(19) United States
(12) Patent Application Publication
(10) Pub. No.: US 2026/0149359 A1
(43) Pub. Date: May 28, 2026

(54) INPUT CIRCUIT

(71) Applicant: Socionext Inc., Kanagawa (JP)

(72) Inventor: Kyota SHIMIZU, Yokohama-shi (JP)

(21) Appl. No.: 19/453,552

(22) Filed: Jan. 20, 2026

Related U.S. Application Data
(63) Continuation of application No. PCT/JP2023/030281, filed on Aug. 23, 2023.

(51) Int. Cl. H02M 1/088; H03K 17/041

(52) U.S. Cl. CPC H02M 1/088; H03K 17/04106

(57) ABSTRACT

An input circuit includes an input buffer, a first voltage conversion circuit, a second voltage conversion circuit, and a third voltage conversion circuit. The input buffer includes: first and second transistors serially connected between a first power supply and an output terminal; and third and fourth transistors serially connected between a second power supply and the output terminal. The first voltage conversion circuit is provided between an input terminal and a second node connected to the gate of the first transistor. The second voltage conversion circuit is provided between the input terminal and a fifth node connected to the gate of the third transistor. The third voltage conversion circuit is provided between the second node and a third node connected to the gates of the second transistor and the fourth transistor.

### CROSS-REFERENCE TO RELATED APPLICATIONS

This is a continuation of International Application No. PCT/JP2023/030281 filed on Aug. 23, 2023. The entire disclosure of this application is incorporated by reference herein.

### BACKGROUND

The present disclosure relates to an input circuit that receives a signal from outside an LSI (hereinafter such a circuit is simply called the input circuit).

With the miniaturization of transistors constituting an LSI, the transistor-tolerable voltage stress (hereinafter called the “withstanding voltage”) is increasingly decreasing. This may cause an occurrence of a signal having a voltage exceeding the withstanding voltage of transistors being input into an input circuit from outside the LSI. To address this, there is known an input circuit having a conversion circuit that converts the voltage of an input signal input from outside the LSI to a voltage falling within the withstanding voltage of transistors.

For example, U.S. Pat. No. 11,190,187 discloses an input circuit provided with a conversion circuit as described above.

However, as the miniaturization of semiconductor devices further proceeds causing further decrease in the withstanding voltage of transistors, a voltage exceeding the withstanding voltage may be input into transistors and this may cause aging degradation of the transistors.

It is therefore required to provide an input circuit that converts the voltage of an input signal to an appropriate voltage even when the withstanding voltage of transistors further decreases, thereby preventing aging degradation of the transistors.

An objective of the present disclosure is resolving the above-described problem.

### SUMMARY

According to one mode of the disclosure, an input circuit includes an input buffer, a first voltage conversion circuit, a second voltage conversion circuit, and a third voltage conversion circuit. The input buffer includes: a first transistor of a first conductivity type having a source connected to a first power supply, a drain connected to a first node, and a gate connected to a second node; a second transistor of the first conductivity type having a source connected to the first node, a drain connected to an output terminal, and a gate connected to a third node; a third transistor of a second conductivity type having a source connected to a second power supply, a drain connected to a fourth node, and a gate connected to a fifth node; and a fourth transistor of the second conductivity type having a source connected to the fourth node, a drain connected to the output terminal, and a gate connected to the third node. The first voltage conversion circuit includes: a fifth transistor of the first conductivity type provided between an input terminal and the second node and having a gate connected to a first bias power supply; and a sixth transistor of the first conductivity type provided between the first bias power supply and the second node and having a gate connected to the input terminal. The second voltage conversion circuit includes: a seventh transistor of the second conductivity type provided between the input terminal and the fifth node and having a gate connected to a second bias power supply; and an eighth transistor of the second conductivity type provided between the second bias power supply and the fifth node and having a gate connected to the input terminal. The third voltage conversion circuit includes: a ninth transistor of the second conductivity type provided between the second node and the third node and having a gate connected to the second bias power supply; and a tenth transistor of the second conductivity type provided between the second bias power supply and the third node and having a gate connected to the second node.

According to the present disclosure, aging degradation of transistors can be prevented.

### BRIEF DESCRIPTION OF THE DRAWINGS

FIG. 1 is a circuit diagram showing a configuration example of an input circuit according to the first embodiment.

FIG. 2 is a view showing an example of voltage transition during operation of the input circuit according to the first embodiment.

FIG. 3 is a circuit diagram showing a configuration example of an input circuit according to the second embodiment.

FIG. 4 is a circuit diagram showing a configuration example of an input circuit according to the third embodiment.

FIG. 5 is a circuit diagram showing a configuration example of an input circuit according to the fourth embodiment.

FIG. 6 is a circuit diagram showing a configuration example of an input circuit according to the fifth embodiment.

FIG. 7 is a view showing an example of voltage transition during operation of the input circuit according to the fifth embodiment.

FIG. 8 is a circuit diagram showing a configuration example of an input circuit according to the sixth embodiment.

FIG. 9 is a circuit diagram showing a configuration example of an input circuit according to the seventh embodiment.

FIG. 10 is a circuit diagram showing a configuration example of an input circuit according to the eighth embodiment.

### DETAILED DESCRIPTION

Embodiments of the present disclosure will be described hereinafter with reference to the accompanying drawings. Note that a power supply node and a power supply voltage supplied to the power supply node may be described using the same reference character. Also, a terminal and a signal passing through the terminal, and a node and a signal passing through the node, may be described using the same reference characters.

An LSI has circuits largely grouped into: internal circuits that drive transistors comparatively low in withstanding voltage at a low voltage; and interface circuits that drive transistors comparatively high in withstanding voltage at a high voltage at the time of signal reception/transmission from/to outside the LSI. The input circuit according to the present disclosure is mainly included in the interface circuits.

### First Embodiment

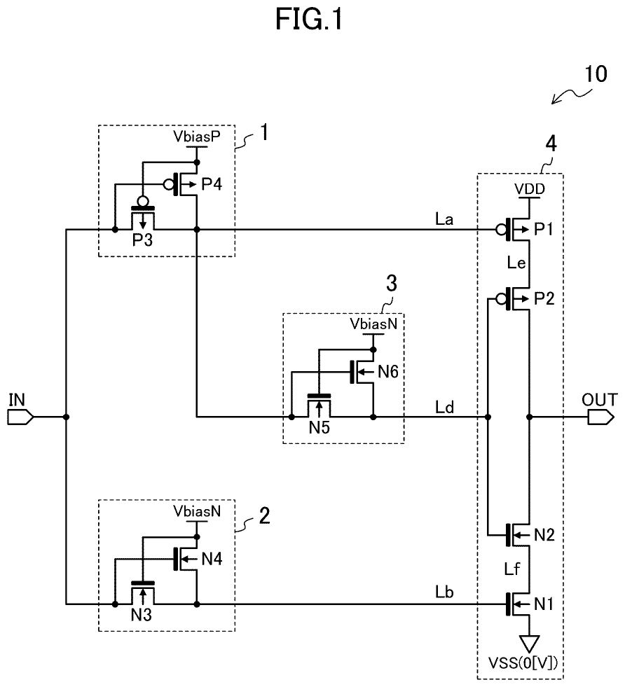

An input circuit 10 according to this embodiment will be described with reference to FIG. 1.

The input circuit 10 of this embodiment includes an input buffer 4, a first voltage conversion circuit 1, a second voltage conversion circuit 2, and a third voltage conversion circuit 3.

### —Input Buffer—

The input buffer 4 includes: a p-type (corresponding to the first conductivity type) transistor P1 and a p-type transistor P2 serially connected between a power supply VDD (corresponding to the first power supply) and an output terminal OUT; and an n-type (corresponding to the second conductivity type) transistor N2 and an n-type transistor N1 serially connected between the output terminal OUT and a ground VSS (corresponding to the second power supply).

In the input buffer 4 according to the present disclosure, the gates of the transistor P1 and the transistor P2 are independent from each other, the gates of the transistor N1 and the transistor N2 are independent from each other, and the gate of the transistor P2 and the gate of the transistor N2 are connected to a node Ld (corresponding to the third node).

The transistor P1 (corresponding to the first transistor) has a source connected to the power supply VDD, a drain connected to a node Le (corresponding to the first node), and a gate connected to a node La (corresponding to the second node). The transistor P2 (corresponding to the second transistor) has a source connected to the node Le, a drain connected to the output terminal OUT, and a gate connected to the node Ld. The transistor N1 (corresponding to the third transistor) has a source connected to the ground VSS, a drain connected to a node Lf (corresponding to the fourth node), and a gate connected to a node Lb (corresponding to the fifth node). The transistor N2 (corresponding to the fourth transistor) has a source connected to the node Lf, a drain connected to the output terminal OUT, and a gate connected to the node Ld.

### —First Voltage Conversion Circuit—

The first voltage conversion circuit 1 is provided between an input terminal IN and the node La, and includes a p-type transistor P3 and a p-type transistor P4. The voltage of an input signal IN input into the input terminal IN changes between the voltage VSS and the voltage VDD.

The transistor P3 (corresponding to the fifth transistor) is provided between the input terminal IN and the node La, and has a gate connected to a bias power supply VbiasP (corresponding to the first bias power supply). The transistor P4 (corresponding to the sixth transistor) is provided between the bias power supply VbiasP and the node La, and has a gate connected to the input terminal IN.

The voltage of the bias power supply VbiasP is higher than the voltage of the ground VSS and not higher than the voltage of a bias power supply VbiasN to be described later. The voltage of the bias power supply VbiasN is lower than the voltage of the power supply VDD. That is, the relationship among the power supply voltages is VSS<VbiasP≤VbiasN<VDD.

### —Second Voltage Conversion Circuit—

The second voltage conversion circuit 2 is provided between the input terminal IN and the node Lb, and includes an n-type transistor N3 and an n-type transistor N4.

The transistor N3 (corresponding to the seventh transistor) is provided between the input terminal IN and the node Lb, and has a gate connected to the bias power supply VbiasN (corresponding to the second bias power supply). The transistor N4 (corresponding to the eighth transistor) is provided between the bias power supply VbiasN and the node Lb, and has a gate connected to the input terminal IN.

### —Third Voltage Conversion Circuit—

The third voltage conversion circuit 3 is provided between the node La and the node Ld, and includes an n-type transistor N5 and an n-type transistor N6. The configuration of the third voltage conversion circuit 3 is the same as that of the second voltage conversion circuit 2.

The transistor N5 (corresponding to the ninth transistor) is provided between the node La and the node Ld, and has a gate connected to the bias power supply VbiasN. The transistor N6 (corresponding to the tenth transistor) is provided between the bias power supply VbiasN and the node Ld, and has a gate connected to the node La.

### —Operation of Input Circuit—

Next, the operation of the input circuit 10 will be described. Note that, in the following description, the voltages of the terminals and the nodes will be expressed as “(terminal or node name)=(character indicating voltage).” Specifically, when the voltage of the input terminal IN is VDD (voltage of the power supply VDD), the expression is IN=VDD. Similarly, when the voltage of the node La is VbiasP (voltage of the first bias power supply), the expression is La=VbiasP. This also applies to the embodiments to follow.

When IN=VSS, the transistor P3 is OFF and the transistor P4 is ON, whereby La=VbiasP. This turns ON the transistor N5 and turns OFF the transistor N6, whereby Ld=VbiasP. Also, the transistor N3 is ON and the transistor N4 is OFF, whereby Lb=VSS. As a result, the transistor P1 and the transistor P2 turn ON and the transistor N1 turns OFF, whereby OUT=VDD.

When IN=VDD, the transistor P3 is ON and the transistor P4 is OFF, whereby La=VDD. This turns OFF the transistor N5 and turns ON the transistor N6, whereby Ld=VbiasN. Also, the transistor N3 is OFF and the transistor N4 is ON, whereby Lb=VbiasN. As a result, the transistor P1 turns OFF and the transistor N1 and the transistor N2 turn ON, whereby OUT=VSS.

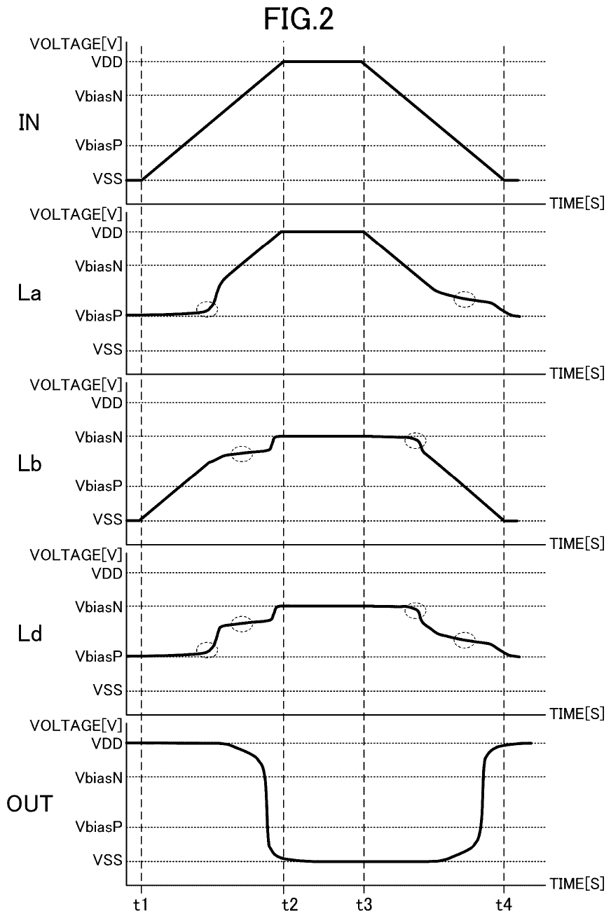

Table 1 below indicates the voltages of the nodes when IN=VSS and when IN=VDD. Also, FIG. 2 shows transitions of the voltages of the nodes observed when the input signal IN changes linearly from VSS to VDD from time t1 to time t2 and thereafter changes linearly from VDD to VSS from time t3 to time t4.

TABLE 1

| | | | | |
|---|---|---|---|---|
| IN | La | Lb | Ld | OUT |
| VDD | VDD | VbiasN | VbiasN | VSS |
| VSS | VbiasP | VSS | VbiasP | VDD |

As shown in Table 1, the terminal-terminal voltages of the transistors depend on VDD, VbiasP, and VbiasN. Specifically, when IN=VDD, the gate-drain voltage of the transistor P2, i.e., the potential difference between the node Ld and the output terminal OUT is VbiasN. Also, when IN=VSS, the gate-drain voltage of the transistor N2, i.e., the potential difference between the node Ld and the output terminal OUT is “VDD−VbiasP.” In addition, as also shown in FIG. 2, the voltage of the node Ld, which corresponds to the voltage range of the gates (X and Y) of the transistors M2 and M3 in the cited patent document, makes transitions between VbiasP and VbiasN.

Therefore, by determining the values of VbiasP and VbiasN (bias power supply voltage values) so as not to exceed the withstanding voltages of the transistor P2 and the transistor N2, for example, aging degradation of the transistors can be prevented. Also, even when the transistor withstanding voltages further decrease in increasingly miniaturized semiconductor devices, aging degradation can also be prevented.

Note that, in this embodiment, VbiasP=VbiasN can be set as far as this does not exceed the withstanding voltages of the transistors. Moreover, the bias power supply VbiasP and/or the bias power supply VbiasN can be replaced with a voltage in the internal circuits. This can reduce the number of power supplies. Also, since the input circuit 10 of this embodiment can be configured using transistors low in withstanding voltage as those in the internal circuits, it has a feature of being also applicable to semiconductor devices having no transistors high in withstanding voltage. This also applies to the embodiments to follow.

### Second Embodiment

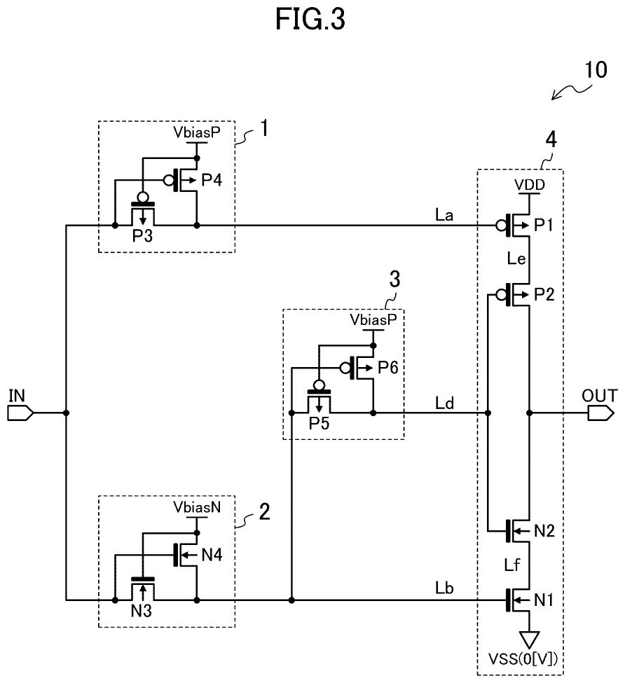

Next, referring to FIG. 3, an input circuit 10 according to this embodiment will be described. In FIG. 3, components corresponding to those in FIG. 1 are denoted by the same reference characters. Note however that, in this embodiment (FIG. 3), there is no intention to put limitations on the components denoted by the same reference characters as those in the first embodiment (FIG. 1). That is, it is acceptable for the components denoted by the same reference characters as those in the first embodiment to be different in voltages, characteristics, and the like from those in the first embodiment. This also applies to the relationship between this embodiment and any other embodiment and between any embodiments other than this embodiment.

Note also that the following description will be made centering on differences from the first embodiment, and duplicate description may be omitted.

In this embodiment, as shown in FIG. 3, the configuration of the third voltage conversion circuit 3 is different from that in the first embodiment (FIG. 1). In this embodiment, as for the transistors, the n-type transistors correspond to the transistors of the first conductivity type, and the p-type transistors correspond to the transistors of the second conductivity type. As for the power supplies, the ground VSS corresponds to the first power supply, the power supply VDD corresponds to the second power supply, and the bias power supply VbiasN corresponds to the first bias power supply, and the bias power supply VbiasP corresponds to the second bias power supply. As for the nodes, the node Lf corresponds to the first node, the node Lb corresponds to the second node, the node Ld corresponds to the third node, the node Le corresponds to the fourth node, and the node La corresponds to the fifth node.

### —Third Voltage Conversion Circuit—

The third voltage conversion circuit 3 is provided between the node Lb and the node Ld, and includes a p-type transistor P5 and a p-type transistor P6. The configuration of the third voltage conversion circuit 3 is the same as that of the first voltage conversion circuit 1.

The transistor P5 (corresponding to the ninth transistor) is provided between the node Lb and the node Ld, and has a gate connected to the bias power supply VbiasP. The transistor P6 (corresponding to the tenth transistor) is provided between the bias power supply VbiasP and the node Ld, and has a gate connected to the node Lb.

Note that, in this embodiment, in the input buffer 4, the transistor N1 corresponds to the first transistor of the first conductivity type, the transistor N2 corresponds to the second transistor of the first conductivity type, the transistor P1 corresponds to the third transistor of the second conductivity type, and the transistor P2 corresponds to the fourth transistor of the second conductivity type.

In the first voltage conversion circuit 1 (corresponding to the second voltage conversion circuit), the transistor P3 corresponds to the seventh transistor of the second conductivity type, and the transistor P4 corresponds to the eighth transistor of the second conductivity type.

In the second voltage conversion circuit 2 (corresponding to the first voltage conversion circuit), the transistor N3 corresponds to the fifth transistor of the first conductivity type, and the transistor N4 corresponds to the sixth transistor of the first conductivity type.

### —Operation of Input Circuit—

Next, the operation of the input circuit 10 will be described.

When IN=VSS, the transistor N3 is ON and the transistor N4 is OFF, whereby Lb=VSS. This turns OFF the transistor P5 and turns ON the transistor P6, whereby Ld=VbiasP. Also, the transistor P3 is OFF and the transistor P4 is ON, whereby La=VbiasP. This turns ON the transistor P1 and the transistor P2 and turns OFF the transistor N1, whereby OUT=VDD.

When IN=VDD, the transistor N3 is OFF and the transistor N4 is ON, whereby Lb=VbiasN. This turns ON the transistor P5 and turns OFF the transistor P6, whereby Ld=VbiasN. Also, the transistor P3 is ON and the transistor P4 is OFF, whereby La=VDD. This turns OFF the transistor P1 and turns ON the transistor N1 and the transistor N2, whereby OUT=VSS.

Table 2 below indicates the voltages of the nodes when IN=VSS and when IN=VDD.

TABLE 2

| | | | | |
|---|---|---|---|---|
| IN | La | Lb | Ld | OUT |
| VDD | VDD | VbiasN | VbiasN | VSS |
| VSS | VbiasP | VSS | VbiasP | VDD |

As shown in Table 2, the voltages of the nodes with respect to the input voltage IN are the same as those in the first embodiment. Although illustration is omitted, the voltage transitions at the nodes are similar to the waveforms in FIG. 2, and therefore effects similar to those in the first embodiment are obtained.

That is, in this embodiment, as in the first embodiment, the terminal-terminal voltages of the transistors depend on VDD, VbiasP, and VbiasN. Specifically, when IN=VDD, the gate-drain voltage of the transistor P2, i.e., the potential difference between the node Ld and the output terminal OUT is VbiasN. Also, when IN=VSS, the gate-drain voltage of the transistor N2, i.e., the potential difference between the node Ld and the output terminal OUT is “VDD−VbiasP.”

Therefore, by determining the values of VbiasP and VbiasN (bias power supply voltage values) so as not to exceed the withstanding voltages of the transistor P2 and the transistor N2, for example, aging degradation of the transistors can be prevented. Also, even when the transistor withstanding voltages further decrease in increasingly miniaturized semiconductor devices, aging degradation can also be prevented.

### Third Embodiment

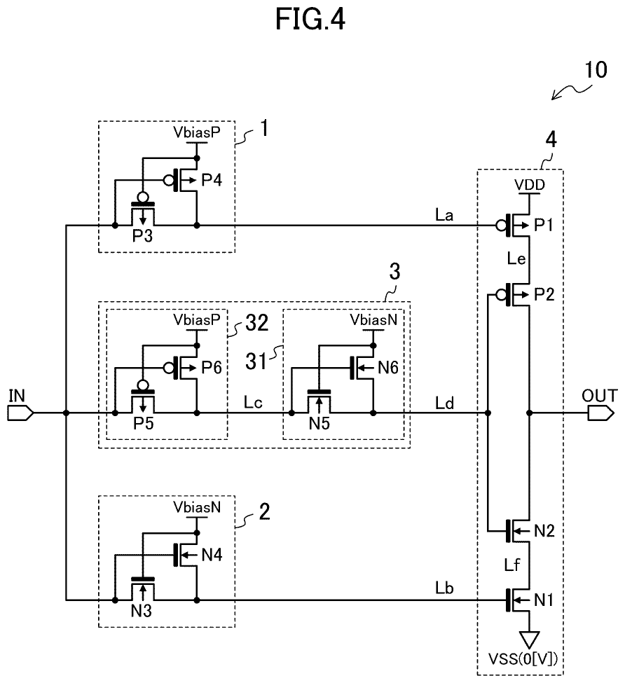

Next, referring to FIG. 4, an input circuit 10 according to this embodiment will be described. In FIG. 4, components corresponding to those in FIG. 1 are denoted by the same reference characters. Note that the following description will be made centering on differences from the first embodiment, and duplicate description may be omitted.

In the first embodiment, since the third voltage conversion circuit 3 is connected to the node La, the load of the first voltage conversion circuit 1 that drives the node La is larger than the load of the second voltage conversion circuit 2 that drives the node Lb. For this reason, a signal propagating through the node La may be delayed relative to a signal propagating through the node Lb. This embodiment is configured to solve this problem.

Specifically, as shown in FIG. 4, the configuration and connection point of the third voltage conversion circuit 3 are different from those in the first embodiment (FIG. 1).

### —Third Voltage Conversion Circuit—

The third voltage conversion circuit 3 is provided between the input terminal IN and the node Ld, and includes a second conversion circuit 32 having the same circuit configuration as the third voltage conversion circuit 3 in the second embodiment and a first conversion circuit 31 having the same circuit configuration as the third voltage conversion circuit 3 in the first embodiment, which are serially connected to each other.

The second conversion circuit 32 is provided between the input terminal IN and a node Lc (corresponding to the sixth node), and includes a p-type transistor P5 and a p-type transistor P6. The transistor P5 (corresponding to the ninth transistor) is provided between the input terminal IN and the node Lc, and has a gate connected to the bias power supply VbiasP. The transistor P6 (corresponding to the tenth transistor) is provided between the bias power supply VbiasP and the node Lc, and has a gate connected to the input terminal IN.

The first conversion circuit 31 is provided between the node Lc and the node Ld, and includes an n-type transistor N5 and an n-type transistor N6. The transistor N5 (corresponding to the eleventh transistor) is provided between the node Lc and the node Ld, and has a gate connected to the bias power supply VbiasN. The transistor N6 (corresponding to the twelfth transistor) is provided between the bias power supply VbiasN and the node Ld, and has a gate connected to the node Lc.

### —Operation of Input Circuit—

Next, the operation of the input circuit 10 will be described. Since the circuit configurations of the first voltage conversion circuit 1, the second voltage conversion circuit 2, and the input buffer 4 are the same as those in the first embodiment, the states of the node La and the node Lb are the same as those in the first embodiment.

Also, since the configuration of the second conversion circuit 32 is the same as that of the first voltage conversion circuit 1, the state of the node La and the state of the node Lc are the same. Moreover, the serial circuit of the second conversion circuit 32 and the first conversion circuit 31 is the same in circuit configuration as the serial circuit of the first voltage conversion circuit 1 and the third voltage conversion circuit 3 in FIG. 1. Therefore, the state of the node Ld in this embodiment is the same as the state of the node Ld in the first embodiment.

Table 3 below indicates the voltages of the nodes when IN=VSS and when IN=VDD.

TABLE 3

| | | | | | |
|---|---|---|---|---|---|
| IN | La | Lb | Lc | Ld | OUT |
| VDD | VDD | VbiasN | VDD | VbiasN | VSS |
| VSS | VbiasP | VSS | VbiasP | VbiasP | VDD |

As described above, in this embodiment, as in the first embodiment, the terminal-terminal voltages of the transistors depend on VDD, VbiasP, and VbiasN. Specifically, when IN=VDD, the gate-drain voltage of the transistor P2, i.e., the potential difference between the node Ld and the output terminal OUT is VbiasN. Also, when IN=VSS, the gate-drain voltage of the transistor N2, i.e., the potential difference between the node Ld and the output terminal OUT is “VDD−VbiasP.”

Therefore, by determining the values of VbiasP and VbiasN (bias power supply voltage values) so as not to exceed the withstanding voltages of the transistor P2 and the transistor N2, for example, aging degradation of the transistors can be prevented. Also, even when the transistor withstanding voltages further decrease in increasingly miniaturized semiconductor devices, aging degradation can also be prevented.

Moreover, by connecting the third voltage conversion circuit 3 between the input terminal IN and the node Ld, the load of the first voltage conversion circuit 1 can be reduced, whereby the delay of a signal at the node La relative to a signal at the node Lb can be reduced. This can shorten the delay time of signals propagating through the circuit and therefore fasten the operation speed of the input circuit 10.

### Fourth Embodiment

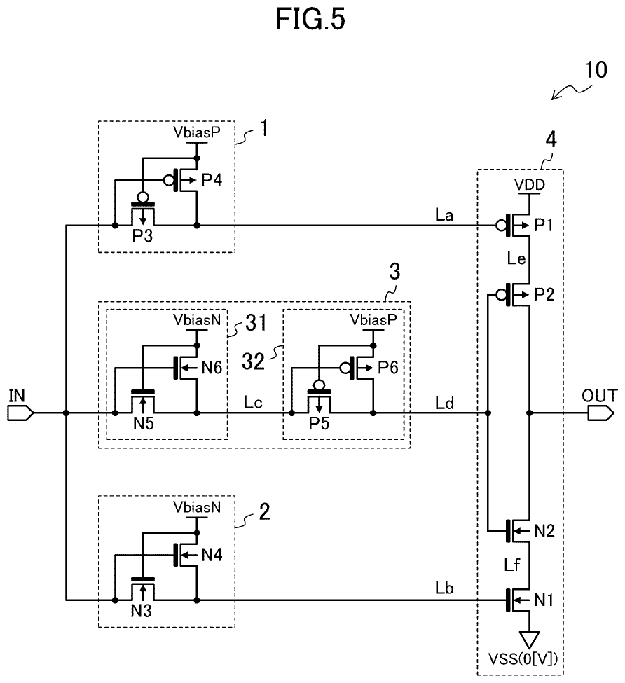

Next, referring to FIG. 5, an input circuit 10 according to this embodiment will be described. In FIG. 5, components corresponding to those in FIG. 3 are denoted by the same reference characters. Note that the following description will be made centering on differences from the second embodiment, and duplicate description may be omitted.

In the second embodiment, since the third voltage conversion circuit 3 is connected to the node Lb, the load of the second voltage conversion circuit 2 that drives the node Lb is larger than the load of the first voltage conversion circuit 1 that drives the node La. For this reason, a signal propagating through the node Lb may be delayed relative to a signal propagating through the node La. This embodiment is configured to solve this problem.

Specifically, as shown in FIG. 5, the configuration and connection point of the third voltage conversion circuit 3 are different from those in the second embodiment (FIG. 3).

### —Third Voltage Conversion Circuit—

The third voltage conversion circuit 3 is provided between the input terminal IN and the node Ld, and includes a first conversion circuit 31 having the same circuit configuration as the third voltage conversion circuit 3 in the first embodiment and a second conversion circuit 32 having the same circuit configuration as the third voltage conversion circuit 3 in the second embodiment, which are serially connected to each other.

The first conversion circuit 31 is provided between the input terminal IN and a node Lc (corresponding to the sixth node), and includes an n-type transistor N5 and an n-type transistor N6. The transistor N5 (corresponding to the ninth transistor) is provided between the input terminal IN and the node Lc, and has a gate connected to the bias power supply VbiasN. The transistor N6 (corresponding to the tenth transistor) is provided between the bias power supply VbiasN and the node Lc, and has a gate connected to the input terminal IN.

The second conversion circuit 32 is provided between the node Lc and the node Ld, and includes a p-type transistor P5 and a p-type transistor P6. The transistor P5 (corresponding to the eleventh transistor) is provided between the node Lc and the node Ld, and has a gate connected to the bias power supply VbiasP. The transistor P6 (corresponding to the twelfth transistor) is provided between the bias power supply VbiasP and the node Ld, and has a gate connected to the node Lc.

### —Operation of Input Circuit—

Next, the operation of the input circuit 10 will be described. Since the circuit configurations of the first voltage conversion circuit 1, the second voltage conversion circuit 2, and the input buffer 4 are the same as those in the second embodiment, the states of the node La and the node Lb are the same as those in the second embodiment.

Also, since the configuration of the first conversion circuit 31 is the same as that of the second voltage conversion circuit 2, the state of the node Lb and the state of the node Lc are the same. Moreover, the serial circuit of the first conversion circuit 31 and the second conversion circuit 32 is the same in circuit configuration as the serial circuit of the second voltage conversion circuit 2 and the third voltage conversion circuit 3 in FIG. 3. Therefore, the state of the node Ld in this embodiment is the same as the state of the node Ld in the second embodiment.

Table 4 below indicates the voltages of the nodes when IN=VSS and when IN=VDD.

TABLE 4

| | | | | | |
|---|---|---|---|---|---|
| IN | La | Lb | Lc | Ld | OUT |
| VDD | VDD | VbiasN | VbiasN | VbiasN | VSS |
| VSS | VbiasP | VSS | VSS | VbiasP | VDD |

As described above, in this embodiment, as in the second embodiment, the terminal-terminal voltages of the transistors depend on VDD, VbiasP, and VbiasN. Specifically, when IN=VDD, the gate-drain voltage of the transistor P2, i.e., the potential difference between the node Ld and the output terminal OUT is VbiasN. Also, when IN=VSS, the gate-drain voltage of the transistor N2, i.e., the potential difference between the node Ld and the output terminal OUT is “VDD−VbiasP.”

### Fifth Embodiment

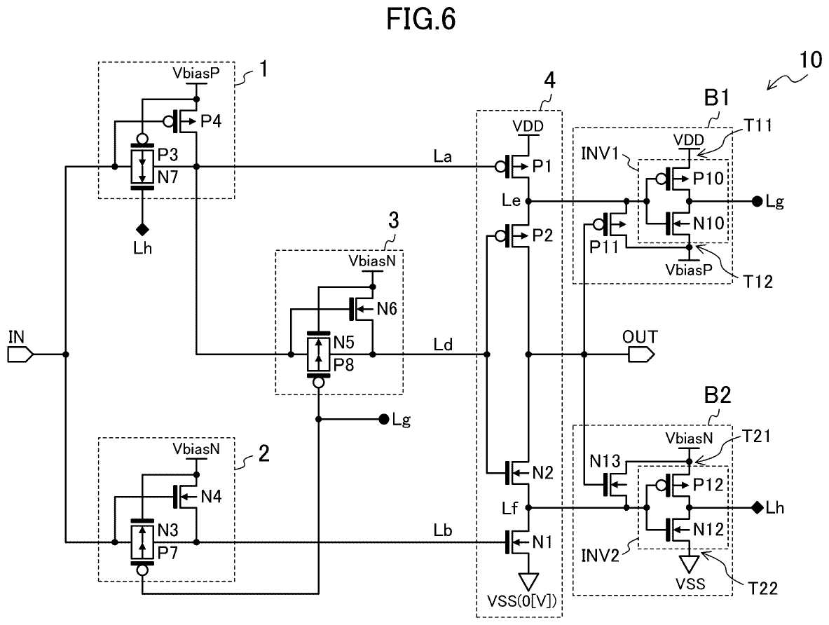

Next, referring to FIG. 6, an input circuit 10 according to this embodiment will be described. In FIG. 6, components corresponding to those in FIG. 1 are denoted by the same reference characters. Note that the following description will be made centering on differences from the first embodiment, and duplicate description may be omitted.

In the first embodiment, during the transition of the input voltage IN from VSS to VDD, the transistor P4 turns ON when “IN≤VbiasP−Vthp (Vthp=threshold of p-type transistor),” and, with the transistor P4 turning ON, the bias power supply VbiasP and the node La are brought into continuity. The transistor P3 turns ON when “IN≥VbiasP+Vthp,” and, with the transistor P3 turning ON, the input terminal IN and the node La are brought into continuity. Also, during the time when “VbiasP−Vthp<IN<VbiasP+Vthp, both the transistor P3 and the transistor P4 are OFF. The transistor N3 turns ON when “IN≤VbiasN−Vthn (Vthn=threshold of n-type transistor),” and, with the transistor N3 turning ON, the input terminal IN and the node Lb are brought into continuity. The transistor N4 turns ON when “IN≥VbiasN+Vthn,” and, with the transistor N4 turning ON, the bias power supply VbiasN and the node Lb are brought into continuity. Also, during the time when “VbiasN−Vthn<IN<VbiasN+Vthn,” both the transistor N3 and the transistor N4 are OFF. Similarly, the transistor N5 and the transistor N6 are both OFF during the time when “VbiasN−Vthn<La<VbiasN+Vthn.” In each of the voltage conversion circuits 1 to 3, no signal is propagated during the time when the above transistors are OFF. Given this situation, as shown in the dotted circles in FIG. 2, there are cases where the transitions at the nodes La, Lb, and Ld become sluggish or unstable. As a result, the signal change at the output terminal OUT may be delayed. In view of this, this embodiment is configured to solve the above-described problem.

In this embodiment, in comparison with the circuit configuration of FIG. 1, a first buffer circuit B1 and a second buffer circuit B2 are additionally provided. Also, transistors are added to the first voltage conversion circuit 1, the second voltage conversion circuit 2, and the third voltage conversion circuit 3.

### —First Buffer Circuit—

The first buffer circuit B1 includes a p-type transistor P11 and a first inverter INV1. The transistor P11 (corresponding to the eleventh transistor) has a source connected to the node Le, a drain connected to the bias power supply VbiasP, and a gate connected to the output terminal OUT. The first inverter INV1 is provided between the node Le and a node Lg (corresponding to the sixth node). The first inverter INV1 has a first power supply terminal T11 connected to the power supply VDD and a second power supply terminal T12 connected to the bias power supply VbiasP.

### —Second Buffer Circuit—

The second buffer circuit B2 includes an n-type transistor N13 and a second inverter INV2. The transistor N13 (corresponding to the twelfth transistor) has a source connected to the node Lf, a drain connected to the bias power supply VbiasN, and a gate connected to the output terminal OUT. The second inverter INV2 is provided between the node Lf and a node Lh (corresponding to the seventh node). The second inverter INV2 has a first power supply terminal T21 connected to the bias power supply VbiasN and a second power supply terminal T22 connected to the ground VSS.

In addition to the circuit configuration in the first embodiment, the first voltage conversion circuit 1 further includes an n-type transistor N7 (corresponding to the thirteenth transistor) provided between the input terminal IN and the node La and having a gate connected to the node Lh. The second voltage conversion circuit 2 further includes a p-type transistor P7 (corresponding to the fourteenth transistor) provided between the input terminal IN and the node Lb and having a gate connected to the node Lg. The third voltage conversion circuit 3 further includes a p-type transistor P8 (corresponding to the fifteenth transistor) provided between the node La and the node Ld and having a gate connected to the node Lg.

### —Operation of Input Circuit—

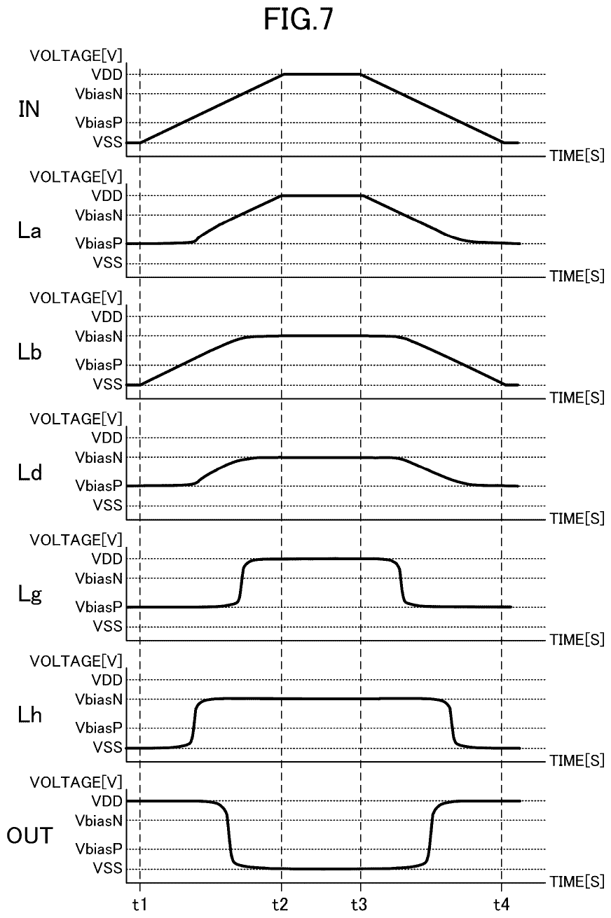

Next, the operation of the input circuit 10 will be described with reference to FIG. 7. Description here will be made centering on differences from the first embodiment.

First, when IN=VSS at time t1, the transistor P1 and the transistor P2 are ON, whereby Le=VDD and Lg=VbiasP, and therefore the transistor P7 and the transistor P8 are OFF. Also, the transistor N1 and the transistor N2 are OFF, and the transistor N13 is ON, whereby Lf=VbiasN and Lh=VSS, and therefore the transistor N7 is OFF.

During the transition from IN=VSS to IN=VDD from time t1 to time t2, the transistor N3 turns ON, raising the voltage of the node Lb, and this turns ON the transistor N1, whereby the voltages of the output terminal OUT and the node LF fall. During this transition, the transistor N13 turns OFF, and the second inverter INV2 is inverted, whereby Lh=VbiasN. Therefore, the transistor N7 turns ON during the time when “IN≤VbiasN−Vthn.” This indicates that the transistor N7 is to be ON during the time when “VbiasP−Vthp<IN≤VbiasN−Vthn,” which corresponds to the time when both the transistor P3 and the transistor P4 are OFF in the first embodiment, whereby the input terminal IN and the node La are brought into conduction. As a result, the voltage of the node La rises with the rise of the voltage of the input terminal IN (see FIG. 7).

Also, during the transition from IN=VSS to IN=VDD, the transistor P7 turns ON during the time when “IN≥VbiasP+Vthp.” This indicates that the transistor P7 is to be ON during the time when “VbiasP+Vthp≤IN<VbiasN+Vthn,” which corresponds to the time when the transistor N3 and the transistor N4 are OFF in the first embodiment, whereby the input terminal IN and the node Lb are brought into conduction. As a result, the voltage of the node Lb rises with the rise of the voltage of the input terminal IN (see FIG. 7).

Similarly, the transistor P8 turns ON during the time when “La≥VbiasP+Vthp.” This indicates that the transistor P8 is to be ON during the time when “VbiasP+Vthp≤La<VbiasN+Vthn,” which corresponds to the time when the transistor N5 and the transistor N6 are OFF, whereby the node La and the node Ld are brought into conduction. As a result, the voltage of the node Ld rises with the transition of the voltage of the node La, i.e., the rise of the voltage of the input terminal IN.

When IN=VDD from time t2 to time t3, the transistor P1 and the transistor P2 are OFF and the transistor P11 is ON, whereby Le=VbiasP and Lg=VDD, and therefore the transistor P7 and the transistor P8 are OFF. Also, the transistor N1 and the transistor N2 are ON and the transistor N13 is OFF, whereby Lf=VSS and Lh=VbiasN, and therefore the transistor N7 is OFF.

During the transition from IN=VDD to IN=VSS from time t3 to time t4, the transistor P7, the transistor P8, and the transistor N7 are ON for the same time period as that during the transition from IN=VSS to IN=VDD, whereby the voltages of the nodes fall with the fall of the voltage of the input terminal IN (see FIG. 7).

As described above, according to this embodiment, the transistor N7, the transistor P7, and the transistor P8 are ON during the time when the common circuits of the voltage conversion circuits 1 to 3 with the first embodiment are OFF. This can improve the problem that the transitions at the nodes become sluggish or unstable, and thus hasten the signal change at the output terminal OUT.

### Sixth Embodiment

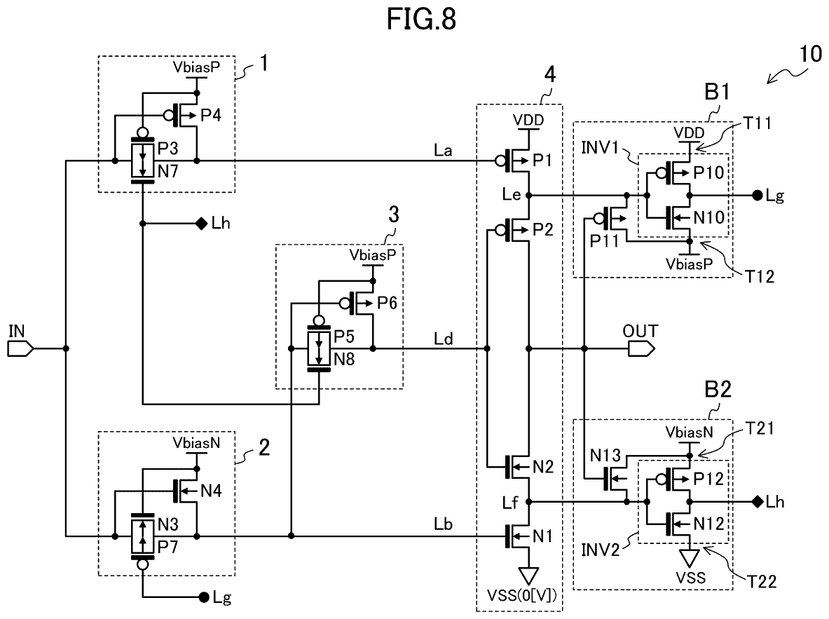

Next, referring to FIG. 8, an input circuit 10 according to this embodiment will be described. In FIG. 8, components corresponding to those in FIG. 6 are denoted by the same reference characters. Note that the following description will be made centering on differences from the fifth embodiment, and duplicate description may be omitted.

In this embodiment, as shown in FIG. 8, the configuration of the third voltage conversion circuit 3 is different from that in the fifth embodiment (FIG. 6). In this embodiment, as for the transistors, the n-type transistors correspond to the transistors of the first conductivity type, and the p-type transistors correspond to the transistors of the second conductivity type. As for the power supplies, the ground VSS corresponds to the first power supply, the power supply VDD corresponds to the second power supply, the bias power supply VbiasN corresponds to the first bias power supply, and the bias power supply VbiasP corresponds to the second bias power supply. As for the nodes, the node Lf corresponds to the first node, the node Lb corresponds to the second node, the node Ld corresponds to the third node, the node Le corresponds to the fourth node, and the node La corresponds to the fifth node.

Like the problem in the first embodiment described in the fifth embodiment, in the second embodiment, also, no signal is propagated in each of the voltage conversion circuits 1 to 3 during the time when the transistors are OFF. Given this situation, there are cases where the transitions at the nodes La, Lb, and Ld become sluggish or unstable. As a result, the signal change at the output terminal OUT may be delayed. In view of this, this embodiment is configured to solve the above-described problem.

### —Third Voltage Conversion Circuit—

The third voltage conversion circuit 3 is provided between the node Lb and the node Ld, and includes a p-type transistor P5, a p-type transistor P6, and an n-type transistor N8. The configuration of the third voltage conversion circuit 3 is the same as that of the first voltage conversion circuit 1.

The transistor P5 (corresponding to the ninth transistor) is provided between the node Lb and the node Ld, and has a gate connected to the bias power supply VbiasP. The transistor P6 (corresponding to the tenth transistor) is provided between the bias power supply VbiasP and the node Ld, and has a gate connected to the node Lb. The transistor N8 (corresponding to the fifteenth transistor) is provided between the node Lb and the node Ld, and has a gate connected to the node Lh.

### —Operation of Input Circuit—

Next, the operation of the input circuit 10 will be described. Description here will be made centering on differences from the fifth embodiment.

First, when IN=VSS at time t1, Lb=VSS and Lh=VSS, and this turns OFF the transistor N8.

During the transition from IN=VSS to IN=VDD from time t1 to time t2, when Lh becomes VbiasN, the transistor N8 turns ON during the time when “Lb≤VbiasN−Vthn.” This indicates that the transistor N8 is to be ON during the time when “VbiasP−Vthp<Lb≤VbiasN−Vthn,” which corresponds to the time when the transistor P5 and the transistor P6 are OFF (same as the time when the transistor P3 and the transistor P4 are OFF), whereby the node Lb and the node Ld are brought into continuity. As a result, the voltage of the node Ld rises with the rise of the voltage of the node Lb, i.e., the rise of the voltage of the input terminal IN.

When IN=VDD from time t2 to time t3, Lb=VbiasN and Lh=VbiasN, and this turns OFF the transistor N8.

During the transition from IN=VDD to IN=VSS from time t3 to time t4, the transistor N8 is ON for the same time period as that during the transition from IN=VSS to IN=VDD, whereby the voltage of the node Ld falls with the fall of the voltage of the node Lb, i.e., the fall of the voltage of the input terminal IN.

In this embodiment, also, effects similar to those in the fifth embodiment are obtained. Specifically, the transistor N7, the transistor N8, and the transistor P7 are ON during the time when the common circuits of the voltage conversion circuits 1 to 3 with the second embodiment are OFF. This can improve the problem that the transitions at the nodes become sluggish or unstable, and thus hasten the signal change at the output terminal OUT.

### Seventh Embodiment

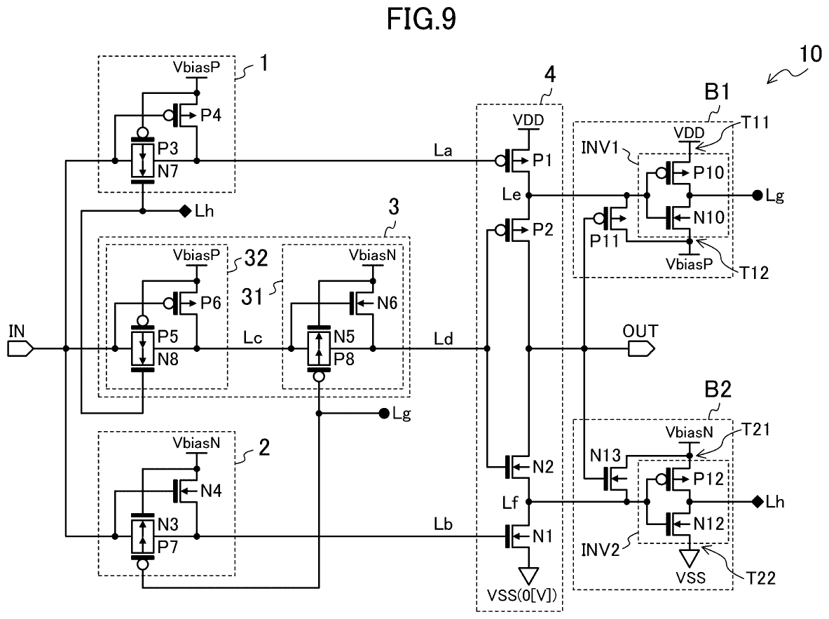

Next, referring to FIG. 9, an input circuit 10 according to this embodiment will be described.

In the third embodiment described above, the configuration of the second conversion circuit 32 of the third voltage conversion circuit 3 is the same as the configuration of the first voltage conversion circuit 1. Therefore, the transition state of the node Lc with the transition at the input terminal IN is the same as that of the node La. Also, the circuit configuration of the third embodiment other than the third voltage conversion circuit 3 is the same as that of the first embodiment. Therefore, the configuration of the third embodiment (see FIG. 4) has the same problem as that described in the fifth embodiment, i.e., the problem that the signal change at the output terminal OUT may be delayed. In view of this, this embodiment is configured to solve the above-described problem.

The input circuit 10 according to this embodiment has a configuration like a combined one of the third embodiment and the fifth embodiment. Specifically, the input circuit of this embodiment includes a first buffer circuit B1 and a second buffer circuit B2 as in the fifth embodiment, in addition to the circuit configuration of the third embodiment. Also, transistors are additionally provided in the first voltage conversion circuit 1, the second voltage conversion circuit 2, and the third voltage conversion circuit 3 in the third embodiment.

Specifically, in addition to the circuit configuration of the third embodiment, the first voltage conversion circuit 1 further includes an n-type transistor N7 (corresponding to the fifteenth transistor) provided between the input terminal IN and the node La and having a gate connected to the node Lh. The second voltage conversion circuit 2 further includes a p-type transistor P7 (corresponding to the sixteenth transistor) provided between the input terminal IN and the node Lb and having a gate connected to the node Lg. The third voltage conversion circuit 3 further includes: an n-type transistor N8 (corresponding to the seventeenth transistor) provided between the input terminal IN and the node Lc and having a gate connected to the node Lh; and a p-type transistor P8 (corresponding to the eighteenth transistor) provided between the node Lc and the node Ld and having a gate connected to the node Lg.

### —Operation of Input Circuit—

In the operation of the input circuit 10, the operation of the transistor N8 is the same as that of the transistor N7 in the fifth embodiment. The operations of the other added components are the same as those in the fifth embodiment. Detailed description is therefore omitted here.

As described above, according to this embodiment, the transistor P7, the transistor P8, the transistor N7, and the transistor N8 are ON during the time when the common circuits of the voltage conversion circuits 1 to 3 with the third embodiment are OFF. This can improve the problem that the transitions at the nodes become sluggish or unstable, and thus hasten the signal change at the output terminal OUT.

### Eighth Embodiment

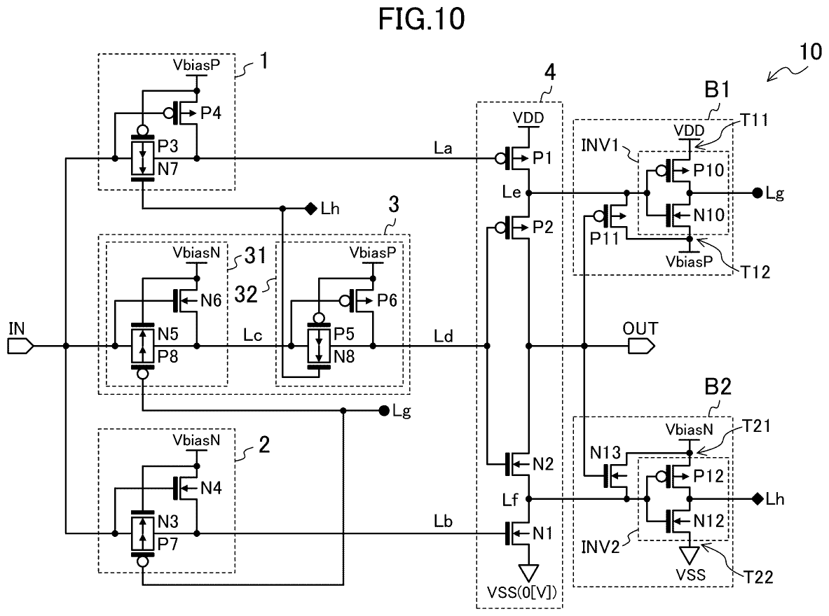

Next, referring to FIG. 10, an input circuit 10 according to this embodiment will be described.

In the fourth embodiment described above, the configuration of the first conversion circuit 31 of the third voltage conversion circuit 3 is the same as the configuration of the second voltage conversion circuit 2. Therefore, the transition state of the node Lc with the transition at the input terminal IN is the same as that of the node Lb. Also, the circuit configuration of the fourth embodiment other than the third voltage conversion circuit 3 is the same as that of the second embodiment. Therefore, the configuration of the fourth embodiment (see FIG. 5) has the same problem as that described in the sixth embodiment, i.e., the problem that the signal change at the output terminal OUT may be delayed. In view of this, this embodiment is configured to solve the above-described problem.

The input circuit 10 according to this embodiment has a configuration like a combined one of the fourth embodiment and the sixth embodiment. Specifically, the input circuit 10 of this embodiment includes a first buffer circuit B1 and a second buffer circuit B2, in addition to the circuit configuration of the fourth embodiment. Also, transistors are additionally provided in the first voltage conversion circuit 1, the second voltage conversion circuit 2, and the third voltage conversion circuit 3 in the fourth embodiment.

Specifically, in addition to the circuit configuration of the fourth embodiment, the first voltage conversion circuit 1 further includes an n-type transistor N7 (corresponding to the fifteenth transistor) provided between the input terminal IN and the node La and having a gate connected to the node Lh. The second voltage conversion circuit 2 further includes a p-type transistor P7 (corresponding to the sixteenth transistor) provided between the input terminal IN and the node Lb and having a gate connected to the node Lg. The third voltage conversion circuit 3 further includes: a p-type transistor P8 (corresponding to the seventeenth transistor) provided between the input terminal IN and the node Lc and having a gate connected to the node Lg; and an n-type transistor N8 (corresponding to the eighteenth transistor) provided between the node Lc and the node Ld and having a gate connected to the node Lh.

### —Operation of Input Circuit—

In the operation of the input circuit 10, the operation of the transistor P8 is the same as that of the transistor P7 in the sixth embodiment. The operations of the other added components are the same as those in the sixth embodiment. Detailed description is therefore omitted here.

As described above, according to this embodiment, the transistor P7, the transistor P8, the transistor N7, and the transistor N8 are ON during the time when the common circuits of the voltage conversion circuits 1 to 3 with the fourth embodiment are OFF. This can improve the problem that the transitions at the nodes become sluggish or unstable, and thus hasten the signal change at the output terminal OUT.

The input circuit according to the present disclosure can prevent aging degradation of transistors even when the transistor withstanding voltages further decrease in increasingly miniaturized semiconductor devices. The present disclosure is therefore very useful.

1. An input circuit comprising an input buffer, a first voltage conversion circuit, a second voltage conversion circuit, and a third voltage conversion circuit, wherein
the input buffer includes
a first transistor of a first conductivity type having a source connected to a first power supply, a drain connected to a first node, and a gate connected to a second node,
a second transistor of the first conductivity type having a source connected to the first node, a drain connected to an output terminal, and a gate connected to a third node,
a third transistor of a second conductivity type having a source connected to a second power supply, a drain connected to a fourth node, and a gate connected to a fifth node, and
a fourth transistor of the second conductivity type having a source connected to the fourth node, a drain connected to the output terminal, and a gate connected to the third node,
the first voltage conversion circuit includes
a fifth transistor of the first conductivity type provided between an input terminal and the second node and having a gate connected to a first bias power supply, and
a sixth transistor of the first conductivity type provided between the first bias power supply and the second node and having a gate connected to the input terminal,
the second voltage conversion circuit includes
a seventh transistor of the second conductivity type provided between the input terminal and the fifth node and having a gate connected to a second bias power supply, and
an eighth transistor of the second conductivity type provided between the second bias power supply and the fifth node and having a gate connected to the input terminal, and
the third voltage conversion circuit includes
a ninth transistor of the second conductivity type provided between the second node and the third node and having a gate connected to the second bias power supply, and
a tenth transistor of the second conductivity type provided between the second bias power supply and the third node and having a gate connected to the second node.

2. The input circuit of claim 1, further comprising:
a first buffer circuit including an eleventh transistor of the first conductivity type having a source connected to the first node, a drain connected to the first bias power supply, and a gate connected to the output terminal and a first inverter provided between the first node and a sixth node and having a first power supply terminal connected to the first power supply and a second power supply terminal connected to the first bias power supply; and
a second buffer circuit including a twelfth transistor of the second conductivity type having a source connected to the fourth node, a drain connected to the second bias power supply, and a gate connected to the output terminal and a second inverter provided between the fourth node and a seventh node and having a first power supply terminal connected to the second bias power supply and a second power supply terminal connected to the second power supply,
wherein
the first voltage conversion circuit includes a thirteenth transistor of the second conductivity type provided between the input terminal and the second node and having a gate connected to the seventh node,
the second voltage conversion circuit includes a fourteenth transistor of the first conductivity type provided between the input terminal and the fifth node and having a gate connected to the sixth node, and
the third voltage conversion circuit includes a fifteenth transistor of the first conductivity type provided between the second node and the third node and having a gate connected to the sixth node.

3. The input circuit of claim 1, wherein
the first conductivity type is p-type, and the second conductivity type is n-type,
the power supply voltage of the first bias power supply is higher than the power supply voltage of the second power supply and not higher than the power supply voltage of the second bias power supply, and
the power supply voltage of the second bias power supply is lower than the power supply voltage of the first power supply.

4. The input circuit of claim 1, wherein
the first conductivity type is n-type, and the second conductivity type is p-type,
the power supply voltage of the second bias power supply is higher than the power supply voltage of the first power supply and not higher than the power supply voltage of the first bias power supply, and
the power supply voltage of the first bias power supply is lower than the power supply voltage of the second power supply.

5. An input circuit comprising an input buffer, a first voltage conversion circuit, a second voltage conversion circuit, and a third voltage conversion circuit, wherein
the input buffer includes
a first transistor of a first conductivity type having a source connected to a first power supply, a drain connected to a first node, and a gate connected to a second node,
a second transistor of the first conductivity type having a source connected to the first node, a drain connected to an output terminal, and a gate connected to a third node,
a third transistor of a second conductivity type having a source connected to a second power supply, a drain connected to a fourth node, and a gate connected to a fifth node, and
a fourth transistor of the second conductivity type having a source connected to the fourth node, a drain connected to the output terminal, and a gate connected to the third node,
the first voltage conversion circuit includes
a fifth transistor of the first conductivity type provided between an input terminal and the second node and having a gate connected to a first bias power supply, and
a sixth transistor of the first conductivity type provided between the first bias power supply and the second node and having a gate connected to the input terminal,
the second voltage conversion circuit includes
a seventh transistor of the second conductivity type provided between the input terminal and the fifth node and having a gate connected to a second bias power supply, and
an eighth transistor of the second conductivity type provided between the second bias power supply and the fifth node and having a gate connected to the input terminal, and
the third voltage conversion circuit includes
a ninth transistor of the first conductivity type provided between the input terminal and a sixth node and having a gate connected to the first bias power supply,
a tenth transistor of the first conductivity type provided between the first bias power supply and the sixth node and having a gate connected to the input terminal,
an eleventh transistor of the second conductivity type provided between the sixth node and the third node and having a gate connected to the second bias power supply, and
a twelfth transistor of the second conductivity type provided between the second bias power supply and the third node and having a gate connected to the sixth node.

6. The input circuit of claim 5, further comprising:
a first buffer circuit including a thirteenth transistor of the first conductivity type having a source connected to the first node, a drain connected to the first bias power supply, and a gate connected to the output terminal and a first inverter provided between the first node and a seventh node and having a first power supply terminal connected to the first power supply and a second power supply terminal connected to the first bias power supply; and
a second buffer circuit including a fourteenth transistor of the second conductivity type having a source connected to the fourth node, a drain connected to the second bias power supply, and a gate connected to the output terminal and a second inverter provided between the fourth node and an eighth node and having a first power supply terminal connected to the second bias power supply and a second power supply terminal connected to the second power supply, wherein
the first voltage conversion circuit includes a fifteenth transistor of the second conductivity type provided between the input terminal and the second node and having a gate connected to the eighth node,
the second voltage conversion circuit includes a sixteenth transistor of the first conductivity type provided between the input terminal and the fifth node and having a gate connected to the seventh node, and
the third voltage conversion circuit includes a seventeenth transistor of the second conductivity type provided between the input terminal and the sixth node and having a gate connected to the eighth node and an eighteenth transistor of the first conductivity type provided between the sixth node and the third node and having a gate connected to the seventh node.

7. The input circuit of claim 5, wherein
the first conductivity type is p-type, and the second conductivity type is n-type,
the power supply voltage of the first bias power supply is higher than the power supply voltage of the second power supply and not higher than the power supply voltage of the second bias power supply, and
the power supply voltage of the second bias power supply is lower than the power supply voltage of the first power supply.

8. The input circuit of claim 5, wherein
the first conductivity type is n-type, and the second conductivity type is p-type,
the power supply voltage of the second bias power supply is higher than the power supply voltage of the first power supply and not higher than the power supply voltage of the first bias power supply, and
the power supply voltage of the first bias power supply is lower than the power supply voltage of the second power supply.

9. The input circuit of claim 2, wherein
the first conductivity type is p-type, and the second conductivity type is n-type,
the power supply voltage of the first bias power supply is higher than the power supply voltage of the second power supply and not higher than the power supply voltage of the second bias power supply, and
the power supply voltage of the second bias power supply is lower than the power supply voltage of the first power supply.

10. The input circuit of claim 2, wherein
the first conductivity type is n-type, and the second conductivity type is p-type,
the power supply voltage of the second bias power supply is higher than the power supply voltage of the first power supply and not higher than the power supply voltage of the first bias power supply, and
the power supply voltage of the first bias power supply is lower than the power supply voltage of the second power supply.

11. The input circuit of claim 6, wherein
the first conductivity type is p-type, and the second conductivity type is n-type,
the power supply voltage of the first bias power supply is higher than the power supply voltage of the second power supply and not higher than the power supply voltage of the second bias power supply, and
the power supply voltage of the second bias power supply is lower than the power supply voltage of the first power supply.

12. The input circuit of claim 6, wherein
the first conductivity type is n-type, and the second conductivity type is p-type,
the power supply voltage of the second bias power supply is higher than the power supply voltage of the first power supply and not higher than the power supply voltage of the first bias power supply, and
the power supply voltage of the first bias power supply is lower than the power supply voltage of the second power supply.
